(19) United States
(12) Patent Application Publication
(10) Pub. No.: US 2026/0090272 A1
(43) Pub. Date: Mar. 26, 2026

(54) PI-TYPE THERMOELECTRIC CONVERSION MODULE

(71) Applicant: LINTEC Corporation, Tokyo (JP)

(72) Inventors: Nozomu MOTOHASHI, Tokyo (JP); Kazuhiro KIKUCHI, Wako-shi (JP)

(73) Assignee: LINTEC Corporation, Tokyo (JP)

(21) Appl. No.: 19/339,679

(22) Filed: Sep. 25, 2025

(30) Foreign Application Priority Data
Sep. 26, 2024 (JP) 2024-167820

(51) Int. Cl. H10N 10/17

(52) U.S. Cl. CPC H10N 10/17

(57) ABSTRACT

Provided is a π-type thermoelectric conversion module having excellent cooling performance with suppressed back-flow of heat, including: a pair of a first substrate including a first electrode and second substrate including a second electrode, the first substrate and the second substrate opposing each other; a thermoelectric conversion member A including a thermoelectric conversion element M; and a heat back-flow suppression member B including a thermoelectric conversion element K, the thermoelectric conversion member A and the heat back-flow suppression member B being arranged alternately and apart from each other between the first and second substrates, and electrically connected in series via the first electrode on the first substrate and the second electrode on the second substrate, in which carriers of the thermoelectric conversion element M and the thermoelectric conversion element K are different from each other, one of the carriers being a hole and the other of the carriers being an electron, and a sum S_{A} (m²) of areas of surface sides of the thermoelectric conversion member A bonded to the first electrode and the second electrode is larger than a sum S_{B} (m²) of areas of surface sides of the heat back-flow suppression member B bonded to the first electrode and the second electrode.

### CROSS-REFERENCE TO RELATED APPLICATION

This application is based upon and claims the benefit of priority from the prior Japanese Patent Application No. 2024-167820, filed on Sep. 26, 2024; the entire contents of which are incorporated herein by reference.

### TECHNICAL FIELD

The present invention relates to a π-type thermoelectric conversion module.

### BACKGROUND ART

In the related art, one means for effectively utilizing energy is a device that directly inter-converts thermal energy and electrical energy using a thermoelectric conversion module having a thermoelectric effect such as a Seebeck effect or a Peltier effect.

As such a thermoelectric conversion module, use of a so-called π-type thermoelectric conversion element is known.

The π-type thermoelectric conversion element is configured with a basic unit in which a pair of electrodes spaced apart from each other are provided on a substrate, for example, a lower surface of a P-type thermoelectric element is provided on one electrode of the pair of electrodes and a lower surface of an N-type thermoelectric element is provided on the other electrode of the pair of electrodes, with the lower surface of the P-type thermoelectric element being spaced apart from the lower surface of the N-type thermoelectric element, and upper surfaces of both P-type thermoelectric element and N-type thermoelectric element are connected to the electrodes on the opposing substrates. A plurality of such basic units are typically formed to achieve electrically serial connection and thermally parallel connection in both of the first and second substrates.

In recent years, for full-scale practical application of products using the π-type thermoelectric conversion module including such π-type thermoelectric conversion elements, there are various demands for further improvement of the thermoelectric performance, high-density configuration, and reduction of constituent materials of the π-type thermoelectric conversion module.

In some cases, there is a significant difference in thermoelectric performance between P-type thermoelectric elements and N-type thermoelectric elements, so that, for example, when a thermoelectric conversion module configured only with the P-type thermoelectric elements is provided, remarkable performance improvement may be expected. In this case, a thermoelectric conversion module configured with only the P-type thermoelectric elements by using conductive members instead of the N-type thermoelectric elements (referred to as a uni-leg-type thermoelectric conversion module) have been devised. However, since the N-type thermoelectric elements are not used in the uni-leg-type thermoelectric conversion module, heat transfer occurs in the conductive member, causing a problem of flowing back of the heat transferred from the P-type thermoelectric elements to the P-type thermoelectric elements.

Patent Document 1 discloses a configuration made of a combination of a P-type thermoelectric conversion element used as a P-type thermoelectric conversion member and a laminate of an N-type thermoelectric conversion element used as an N-type thermoelectric conversion member and a conductive member, as illustrated in, for example, FIG. 3 of Patent Document 1.

### CITATION LIST

### Patent Literature

Patent Document 1: JP 2018-157136 A

### SUMMARY OF INVENTION

However, the thermoelectric conversion module of Patent Document 1 has the above-described configuration merely to suppress the occurrence of thermal stress due to a difference in thermal expansion and contraction between the P-type thermoelectric conversion member and the N-type thermoelectric conversion member in a use environment (100° C., 300° C., 500° C.). In addition, there is no description or suggestion of how the difference in area between upper and lower surface sides of the P-type thermoelectric conversion member and the N-type thermoelectric conversion member bonded to the electrodes affects the thermoelectric performance.

The present invention has been made in view of such circumstances, and it is an object of the present invention to provide a π-type thermoelectric conversion module having suppressed heat back-flow and excellent cooling performance.

As a result of intensive studies to solve the above problem, the inventors of the present invention have found that a configuration of a π-type thermoelectric conversion module including a thermoelectric conversion member A including a thermoelectric conversion element M, and a heat back-flow suppression member B including a thermoelectric conversion element K, the thermoelectric conversion member A and the heat back-flow suppression member B being arranged alternately and apart from each other, in which carriers of the thermoelectric conversion element M and the thermoelectric conversion element K are different from each other, and a sum S_{A} (m²) of areas of surface sides of the thermoelectric conversion member A bonded to the first electrode and the second electrode is larger than a sum S_{B} (m²) of areas of surface sides of the heat back-flow suppression member B bonded to the first electrode and the second electrode has achieved suppressed back-flow of heat between the thermoelectric conversion element M and the thermoelectric conversion element K and excellent cooling performance. Thus, the present invention is completed.

That is, the present invention provides [1] to [4] below.
[1] A π-type thermoelectric conversion module, including a pair of a first substrate including a first electrode and a second substrate including a second electrode, the first substrate and the second substrate opposing each other, a thermoelectric conversion member A including a thermoelectric conversion element M, and a heat back-flow suppression member B including a thermoelectric conversion element K, the thermoelectric conversion member A and the heat back-flow suppression member B being arranged alternately and apart from each other, and electrically connected in series via the first electrode on the first substrate and the second electrode on the second substrate,
in which carriers of the thermoelectric conversion element M and the thermoelectric conversion element K are different from each other, one of the carriers being a hole and the other of the carriers being an electron, and
a sum S_{A} (m²) of areas of surface sides of the thermoelectric conversion member A bonded to the first electrode and the second electrode is larger than a sum S_{B} (m²) of areas of surface sides of the heat back-flow suppression member B bonded to the first electrode and the second electrode.
[2] The π-type thermoelectric conversion module according to [1] above, in which a ratio R [=S_{A}/(S_{A}+S_{B})] of the sum S_{A} of the areas of the surface sides of the thermoelectric conversion member A bonded to the first electrode and the second electrode to a sum of the sum S_{A} of the areas of the surface sides of the thermoelectric conversion member A bonded to the first electrode and the second electrode and the sum S_{B} of the areas of the surface sides of the heat back-flow suppression member B bonded to the first electrode and the second electrode is 0.55 or more and less than 0.95.
[3] The π-type thermoelectric conversion module according to [1] or [2] above, in which the heat back-flow suppression member B includes the thermoelectric conversion element K and a conductive member, and the thermoelectric conversion element K and the conductive member are laminated in a direction in which the first substrate and the second substrate face each other.
[4] The π-type thermoelectric conversion module according to [3] above, in which a height of the thermoelectric conversion element M in a thickness direction of the thermoelectric conversion member A is greater than a height of the thermoelectric conversion element K in a thickness direction of the heat back-flow suppression member B including the conductive member.

The present invention can provide a π-type thermoelectric conversion module having excellent cooling performance with suppressed heat back-flow.

### BRIEF DESCRIPTION OF DRAWINGS

FIG. 1 is a cross-sectional configuration view of an embodiment (configuration A) of a π-type thermoelectric conversion module according to the present invention.

FIG. 2 is a cross-sectional configuration view of an embodiment (configuration B) of a π-type thermoelectric conversion module according to the present invention.

FIG. 3 is a cross-sectional configuration view of an embodiment (configuration C) of a π-type thermoelectric conversion module of the related art.

FIG. 4 is a cross-sectional configuration view of an embodiment (configuration D) of a π-type thermoelectric conversion module of the related art.

### DESCRIPTION OF EMBODIMENTS

### Thermoelectric Conversion Module

A π-type thermoelectric conversion module of the present invention includes a pair of a first substrate including a first electrode and second substrate including a second electrode, the first substrate and the second substrate opposing each other, a thermoelectric conversion member A including a thermoelectric conversion element M, and a heat back-flow suppression member B including a thermoelectric conversion element K, the thermoelectric conversion member A and the heat back-flow suppression member B arranged alternately and apart from each other, and electrically connected in series via the first electrode on the first substrate and the second electrode on the second substrate,
in which carriers of the thermoelectric conversion element M and the thermoelectric conversion element K are different from each other, one of the carriers being a hole and the other of the carriers being an electron, and
a sum S_{A} (m²) of areas of surface sides of the thermoelectric conversion member A bonded to the first electrode and the second electrode is larger than a sum S_{B} (m²) of areas of surface sides of the heat back-flow suppression member B bonded to the first electrode and the second electrode.

In the present invention, the π-type thermoelectric conversion module includes the thermoelectric conversion member A including the thermoelectric conversion element M and the heat back-flow suppression member B including the thermoelectric conversion element K are arranged alternately and apart from each other, and the carriers (holes and electrons) of the thermoelectric conversion element M and the thermoelectric conversion element K are in different combinations. For example, by combining the thermoelectric conversion element M as a P-type thermoelectric conversion element having holes as carriers and the thermoelectric conversion element K as an N-type thermoelectric conversion element in having electrons as carriers, the back-flow of heat from the heat back-flow suppression member B to the thermoelectric conversion member A can be suppressed as compared with a combination of a thermoelectric conversion element having one type of carriers and a conductive member (in the case of a so-called uni-leg type). The sum S_{A} (m²) of the areas of the surface sides of the thermoelectric conversion member A bonded to the first electrode and the second electrode is set to be larger than the sum S_{B} (m²) of the areas of the surface sides of the heat back-flow suppression member B bonded to the first electrode and the second electrode. This makes it possible to use the thermoelectric conversion member A including the thermoelectric conversion element M having more excellent thermoelectric performance in a relatively large area, and to obtain a π-type thermoelectric conversion module having more excellent cooling performance.

In the present specification, the thermoelectric conversion element M and the thermoelectric conversion element K may be simply referred to as “thermoelectric conversion elements”. The first substrate and the second substrate may be simply referred to as “substrates”. The first electrode and the second electrode may be simply referred to as “electrodes”.

In the present specification, the preferred provisions can be selected as desired, and combinations of the preferred provisions are more preferable.

In the present specification, the description “from XX to YY” means “XX or higher and YY or lower” or “XX or greater and YY or less”.

In the present specification, the lower and upper limits of a preferable numerical range (for example, a range of content) described in series can each be independently combined. For example, from the description “preferably from 10 to 90, and more preferably from 30 to 60”, the “preferred lower limit (10)” and the “more preferred upper limit (60)” can be combined as “from 10 to 60”.

The thermoelectric conversion member A includes the thermoelectric conversion element M.

The heat back-flow suppression member B includes the thermoelectric conversion element K.

The thermoelectric conversion element M and the thermoelectric conversion element K will be described in detail later.

The π-type thermoelectric conversion module according to the present invention will be described below by referring to the drawings.

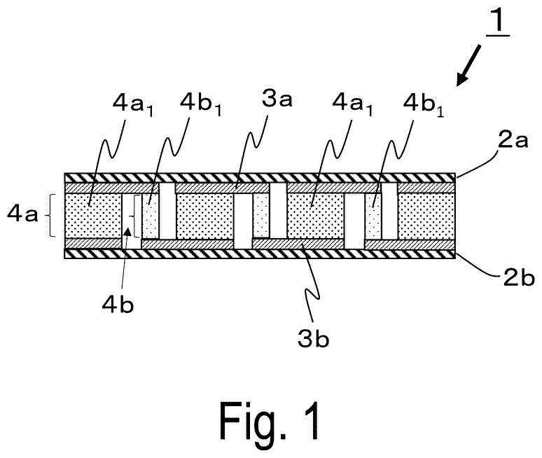

FIG. 1 is a cross-sectional configuration view illustrating an embodiment (configuration A) of the π-type thermoelectric conversion module according to the present invention. A π-type thermoelectric conversion module 1 includes a pair of opposing first substrate 2a having a first electrode 3a and a second substrate 2b having a second electrode 3b, a thermoelectric conversion member A 4a including a thermoelectric conversion element M 4a₁, and a heat back-flow suppression member B 4b including a thermoelectric conversion element K 4b₁. The thermal electric conversion member A 4a and the heat back-flow suppression member B 4b are arranged alternately and apart from each other between the pair of first and second substrates 2a, 2b, and electrically connected in series via the first electrode 3a on the first substrate 2a and the second electrode 3b on the second substrate 2b.

Here, for example, the area of upper and lower surfaces (not illustrated) of the thermoelectric conversion member A 4a including the thermoelectric conversion element M4a₁ bonded to the first electrode 3a side or the second electrode 3b side is configured to be larger than the area of upper and lower surfaces (not illustrated) of the heat back-flow suppression member B4b including the thermoelectric conversion element K4b₁ bonded to the first electrode 3a side or the second electrode 3b side.

A ratio R [=S_{A}/(S_{A}+S_{B})] of the sum S_{A} of the areas of the surface sides of the thermoelectric conversion member A bonded to the first electrode and the second electrode to the sum S_{A} of the areas of the surface sides of the thermoelectric conversion member A bonded to the first electrode and the second electrode and the sum S_{B} of the areas of the surface sides of the heat back-flow suppression member B bonded to the first electrode and the second electrode is preferably 0.55 or more and less than 0.95, more preferably 0.65 or more and less than 0.95, still more preferably from 0.75 to 0.93, and particularly preferably from 0.80 to 0.90.

When the ratio R is 0.55 or more, the heat absorption amount per area of the thermoelectric conversion element M included in the thermoelectric conversion member A can be easily increased.

When the ratio R is less than 0.95, the back-flow of heat from the heat back-flow suppression member B to the thermoelectric conversion member A can be easily suppressed, and the heat absorption amount per unit area of the thermoelectric conversion element K included in the heat back-flow suppression member B can be maintained high.

The heat back-flow suppression member B includes the thermoelectric conversion element K and the conductive member, and the thermoelectric conversion element K and the conductive member are preferably laminated in a direction in which the first substrate and the second substrate face each other.

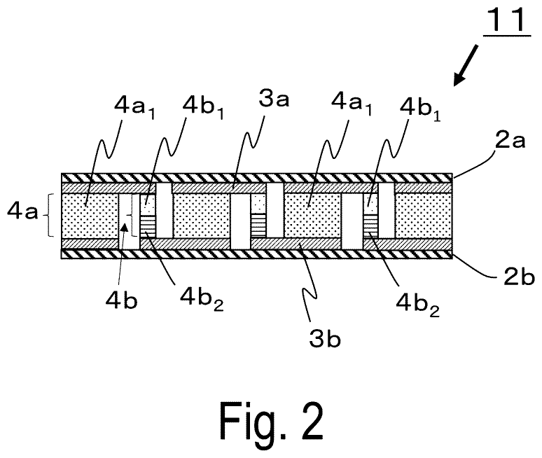

FIG. 2 is a cross-sectional configuration view illustrating an embodiment (configuration B) of the π-type thermoelectric conversion module according to the present invention. A π-type thermoelectric conversion module 11 includes the pair of opposing first substrate 2a having the first electrode 3a and the second substrate 2b having the second electrode 3b, the thermoelectric conversion member A 4a including a thermoelectric conversion element M 4a₁, and the heat back-flow suppression member B4b including the thermoelectric conversion element K 4b₁ and a conductive member K 4b₂. The thermal electric conversion member A 4a and the heat back-flow suppression member B 4b are arranged alternately and apart from each other between the pair of first and second substrates 2a, 2b, and electrically connected in series via the first electrode 3a on the first substrate 2a and the second electrode 3b on the second substrate 2b.

Here, for example, the area of the upper and lower surfaces (not illustrated) of the thermoelectric conversion member A 4a including the thermoelectric conversion element M 4a₁ bonded to the first electrode 3a side or the second electrode 3b side is larger than the area of the upper and lower surfaces (not illustrated) of the heat back-flow suppression member B 4b including the laminate of the thermoelectric conversion element K 4b₁ and the conductive member 4b₂ bonded to the first electrode 3a side or the second electrode 3b side.

### Conductive Member

The conductive member used in the present invention is preferably used as a laminate with the thermoelectric conversion element K. The laminate may be, for example, in a single layer configuration in which the conductive member and the thermoelectric conversion element K are each provided as a single layer, a three layer configuration in which the conductive member is sandwiched between the thermoelectric conversion elements K, or a configuration in which a plurality of layers are alternately laminated.

The conductive member may be composed of a conductive material described later, or may be a thin film composed of a composition containing such conductive materials.

Examples of the conductive material constituting the conductive member include metal materials such as copper, silver, gold, platinum, nickel, aluminum, constantan, chromium, indium, iron, or alloys of these metals, or indium tin oxide (ITO), zinc oxide (ZnO), and the like.

Among these, a material that easily reduces the electrical resistance of the conductive member and increases the thermal resistance is preferably used from the perspective of thermoelectric performance.

A method for forming the conductive member or laminating the conductive member on the thermoelectric conversion element K is not particularly limited, and examples thereof include a dry process such as physical vapor deposition (PVD) such as vacuum vapor deposition, sputtering, or ion plating, or chemical vapor deposition (CVD) such as thermal CVD or atomic layer vapor deposition (ALD), or a known method such as screen printing, flexographic printing, gravure printing, spin coating, dip coating, die coating, spray coating, bar coating, or doctor blading. When the coating film of the composition is formed in a pattern, a method such as screen printing or slot die coating by which the pattern can be easily formed using a screen plate having a desired pattern is preferably used.

The patterning of the conductive member can be performed by known physical or chemical processes mainly using photolithography or a combination thereof.

The height of the thermoelectric conversion element M in the thickness direction of the thermoelectric conversion member A is preferably greater than the height of the thermoelectric conversion element K in the thickness direction of the heat back-flow prevention member B having the conductive member.

By making the height of the thermoelectric conversion element M greater than the height of the thermoelectric conversion element K, the electric resistance value of the thermoelectric conversion element K is suppressed to be low, and a sufficient amount of current can be secured even when the area of the surface of the thermoelectric conversion element K facing the electrode is small. This allows the thermoelectric conversion element K to achieve a more pronounced effect of preventing the back-flow of heat transfer by the thermoelectric conversion member A while ensuring a current flow.

From this perspective, the thickness of the conductive member is not particularly limited, but is appropriately adjusted depending on the thickness of the thermoelectric conversion element K. For example, when the heat back-flow suppression member B is composed of a single layer of the conductive member and a single layer of the thermoelectric conversion element K, the ratio of the thickness of the thermoelectric conversion element K to the thickness of the conductive member is preferably from 1:9 to 9:1, more preferably from 2:8 to 8:2, and still more preferably from 2:8 to 4:6.

The ratio R [=S_{A}/(S_{A}+S_{B})] of the sum S_{A} of the areas of the surface sides of the thermoelectric conversion members A bonded to the first electrode and the second electrode to a sum of the sum S_{A} of the areas of the surface sides of the thermoelectric conversion members A bonded to the first electrode and the second electrode and the sum S_{B} of the areas of the surface sides of the heat back-flow suppression members B bonded to the first electrode and the second electrode is as described above.

A sum S_{A1B1} which is a sum of a sum S_{A1} of the areas of the surface sides the thermoelectric conversion member A bonded to the first electrode and a sum S_{B1} of the areas of the surface sides of the heat back-flow suppression member B bonded to the first electrode, and a sum S_{A2B2} which is a sum of a sum S_{A2} of the areas of the surface sides of the thermoelectric conversion member A bonded to the second electrode and a sum S_{B2} of the areas of the surface sides of the thermoelectric conversion members of the heat back-flow suppression member B bonded to the second electrode may be the same or different, but is preferably the same from the perspective of uniformity of the heat absorption surface.

The sum S_{A1} of the areas of the surface sides of the thermoelectric conversion members A bonded to the first electrode and the sum S_{A2} of the areas of the surface sides of the thermoelectric conversion members A bonded to the second electrode may be the same or different, and are preferably the same.

The sum S_{B1} of the areas of the surface sides of the heat back-flow suppression members B bonded to the first electrode and the sum S_{B2} of the areas of the surface sides of the thermal back-flow suppression members B bonded to the second electrode may be the same or different, and are preferably the same.

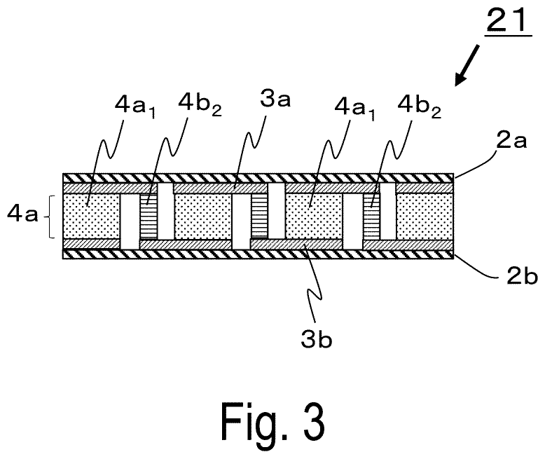

FIG. 3 is a cross-sectional configuration view illustrating an embodiment (configuration C) of a thermoelectric conversion module of the related art. A thermoelectric conversion module 21 is a so-called uni-leg type thermoelectric conversion module, including the pair of opposing first substrate 2a having the first electrode 3a and the second substrate 2b having the second electrode 3b, the thermoelectric conversion member A 4a including the thermoelectric conversion element M 4a₁, and the conductive member 4b₂. The thermoelectric conversion member A 4a and the conductive members 4b₂ are alternately arranged and apart from each other between the pair of first and second substrates 2b, 3b, and the thermoelectric conversion member A 4b and the conductive member 4b₂ are electrically connected in series via the first electrode 3a on the first substrate 2a and the second electrode 3b on the second substrate 2b.

Here, for example, the area of the upper and lower surfaces (not illustrated) of the thermoelectric conversion member A 4a including the thermoelectric conversion element M 4a₁ bonded to the first electrode 3a side or the second electrode 3b side is made to be larger than the area of the upper and lower surfaces (not illustrated) of the conductive member 4b₂ bonded to the first electrode 3a side or the second electrode 3b side.

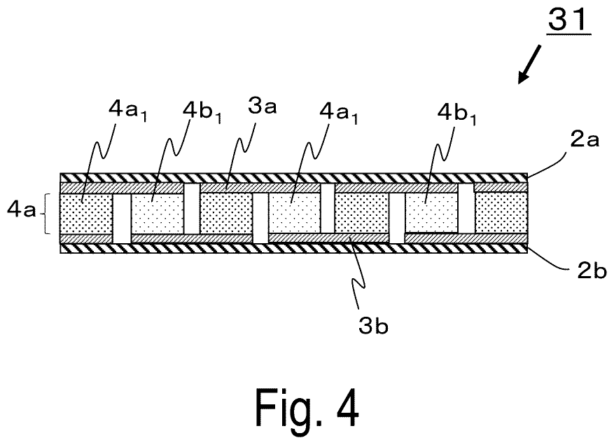

FIG. 4 is a cross-sectional configuration view illustrating an embodiment (configuration D) of a π-type thermoelectric conversion module of the related art. A π-type thermoelectric conversion module 31 includes the pair of opposing first substrate 2a having the first electrode 3a and second substrate 2b having the second electrode 3b, and includes the thermoelectric conversion member A 4a including the thermoelectric conversion element M 4a₁, and the thermoelectric conversion element K 4b₁, which are arranged alternately and apart from each other between the pair of first and second substrates 2a, 2b. In addition, the thermoelectric conversion member A 4a including the thermoelectric conversion element M 4a₁ and the thermoelectric conversion element K 4b₁ are electrically connected in series via the first electrode 3a on the first substrate 2a and the second electrode 3b on the second substrate 2b.

Here, for example, the area of the upper and lower surfaces (not illustrated) of the thermoelectric conversion member A 4a including the thermoelectric conversion element M 4a₁ bonded to the first electrode 3a side or the second electrode 3b side is substantially the same as the area of the upper and lower surfaces (not illustrated) of the thermoelectric conversion element K 4b₁ bonded to the first electrode 3a side or the second electrode 3b side.

### Heat Absorption Amount

A heat absorption amount was calculated by the following thermal simulation.
(a) Heat absorption amount of P-type thermoelectric conversion element and N-type thermoelectric conversion element

A heat absorption amount Qc of the P-type thermoelectric conversion element and the N-type thermoelectric conversion element can be calculated from the following formula (1).

$${Q}_{c} = S e {T}_{c} I - ( λ S / L ) Δ T - ( 1 / 2 ) R {I}^{2} \qquad ( 1 )$$

Q_{c}: Heat absorption amount of thermoelectric conversion element (W/m²)
Se: Seebeck coefficient (V/K)
I: Current value (A) of thermoelectric conversion module
T_{c}: Temperature (K) of the heat absorption surface of thermoelectric conversion module
Tₕ: Temperature (K) of heat dissipation surface of thermoelectric conversion module
ΔT: Temperature difference (Tₕ−T_{c}) (K)
R: Electric resistance value (Ω) of thermoelectric conversion module
A: Thermal conductivity of thermoelectric conversion element (W/(m·K))
L: Height of thermoelectric conversion element (m)
S: Area of thermoelectric conversion element on heat absorption surface side bonded to the first electrode and the second electrode (m²)

The maximum heat absorption amount Q_{CMAX}(W) can be calculated by setting the current value (A) of the thermoelectric conversion module to the maximum current value (A) and setting ΔT to 0 in the above formula (1).

### (b) Heat Transfer Amount of Conductive Member

The heat transfer amount Q_{A} of the conductive member can be calculated from the following formula (2).

$${Q}_{A} = - ( λ S / L ) Δ T \qquad ( 2 )$$

Q_{A}: Heat transfer amount (W/m²)
ΔT: Temperature difference (Tₕ−T_{c}) (K)
ΔT: Thermal conductivity of conductive member [W/(m˜K)]
L: Height L (m) of conductive member
S: Area of conductive member on heat absorption surface side bonded to the first electrode and the second electrode (m²)

### (c) Total Heat Absorption Amount

A total heat absorption amount Q_{F} can be calculated from the following formula (3).

$${Q}_{F} = {Q}_{c} + {Q}_{A} \qquad ( 3 )$$

### Thermoelectric Conversion Element

The thermoelectric conversion elements M of the thermoelectric conversion member A used in the present invention, and the thermoelectric conversion elements K of the heat back-flow suppression member B can be used in combination in a not particularly limited manner when their carriers are different from each other, and may be composed of a thermoelectric semiconductor material or a thin film composed of a thermoelectric semiconductor composition.

From the perspectives of flexibility, thin profile, and thermoelectric performance, the thermoelectric element layer is preferably composed of a thin film composed of a thermoelectric semiconductor composition containing a thermoelectric semiconductor material (hereinafter, also referred to as “thermoelectric semiconductor particles”), a resin, and one or both of an ionic liquid and an inorganic ionic compound.

### Thermoelectric Semiconductor Material

A thermoelectric semiconductor material used in thermoelectric conversion elements M and K is preferably crushed to a predetermined size using a fine grinding device or the like and used as thermoelectric semiconductor particles.

The particle size of the thermoelectric semiconductor particles is preferably from 10 nm to 100 μm.

An average particle size of the thermoelectric semiconductor particles is measured using a laser diffraction particle size analyzer (Mastersizer 3000 available from Malvern Panalytical Ltd.), and the median of the particle size distribution is used as the average particle size.

Examples of the thermoelectric semiconductor material constituting the P-type thermoelectric conversion element and the N-type thermoelectric conversion element in the thermoelectric conversion element M and the thermoelectric conversion element K used in the present invention include:
bismuth-tellurium-based thermoelectric semiconductor materials such as P-type bismuth telluride and N-type bismuth telluride;
telluride-based thermoelectric semiconductor materials such as GeTe and PbTe;
antimony-tellurium-based thermoelectric semiconductor materials;
zinc-antimony-based thermoelectric semiconductor materials such as ZnSb, Zn₃Sb₂, and Zr₄Sb₃;
silicon-germanium-based thermoelectric semiconductor materials such as SiGe; bismuth selenide-based thermoelectric semiconductor materials such as Bi₂Se₃;
silicide-based thermoelectric semiconductor materials such as β-FeSi₂, CrSi₂, MnSi_{1.73}, and Mg₂Si;
oxide-based thermoelectric semiconductor materials;
Heusler materials such as FeVAl, FeVAlSi, and FeVTiAl; and
sulfide-based thermoelectric semiconductor materials such as TiS₂.

The content of the thermoelectric semiconductor particles in the thermoelectric semiconductor composition is preferably from 30 to 99 mass %. When the content of the thermoelectric semiconductor particles is within the range described above, the Seebeck coefficient (absolute value of the Peltier coefficient) is large, a decrease in electrical conductivity is suppressed, and only thermal conductivity is reduced, and therefore a film exhibiting a high thermoelectric performance and having sufficient film strength and flexibility is produced.

Furthermore, the thermoelectric semiconductor particles are preferably subjected to an annealing treatment (hereinafter, also referred to as an “annealing treatment A”). By performing annealing treatment A, the crystallinity of the thermoelectric semiconductor particles is improved. Furthermore, since the surface oxide film of the thermoelectric semiconductor particles is removed, the Seebeck coefficient (absolute value of the Peltier coefficient) of the thermoelectric conversion element increases, thereby further improving the thermoelectric performance index.

### Resin

The resin used in the present invention has a function of physically bonding the thermoelectric semiconductor material (thermoelectric semiconductor particles) together, and can increase the flexibility of the thermoelectric conversion module and facilitate the formation of a thin film through coating or the like.

The resin is preferably a heat-resistant resin or a binder resin.

When crystal growth of the thermoelectric semiconductor particles is caused by subjecting the thin film composed of the thermoelectric semiconductor composition to an annealing treatment or the like, the physical properties such as mechanical strength and thermal conductivity of the heat-resistant resin as a resin are maintained without being impaired.

From the perspective of further increasing heat resistance and not adversely affecting crystal growth of the thermoelectric semiconductor particles in the thin film, the heat-resistant resin is preferably a polyamide resin, a polyamide-imide resin, a polyimide resin, or an epoxy resin, and from the perspective of excelling in flexibility, the heat-resistant resin is more preferably a polyamide resin, a polyamide-imide resin, or a polyimide resin.

The heat-resistant resin preferably has a decomposition temperature of 300° C. or higher. When the decomposition temperature is within the range described above, flexibility can be maintained without loss of function as a binder even when the thin film composed of the thermoelectric semiconductor composition is subjected to annealing treatment as described below.

The content of the heat-resistant resin in the thermoelectric semiconductor composition is preferably from 0.1 to 40 mass %. When the content of the heat-resistant resin is in the range described above, the heat-resistant resin functions as a binder of the thermoelectric semiconductor material and facilitates the formation of a thin film.

The binder resin also facilitates peeling from a base material of glass, alumina, silicon, or the like after a firing (annealing) treatment (corresponding to the “annealing treatment B” described below, same hereinafter), the base material being used when fabricating a chip of a thermoelectric conversion material.

The binder resin is a resin in which 90 mass % or more decomposes at a firing (annealing) temperature. That is, by using a resin that decomposes at lower temperatures than the heat-resistant resin mentioned above, the binder resin decomposes during firing, thereby reducing the content amount of binder resin contained in the fired body that acts as an insulating component. This promotes the crystallization growth of thermoelectric semiconductor particles in the thermoelectric semiconductor composition, thereby reducing the voids in the thermoelectric conversion material layer and improving the filling rate.

Note that whether a resin decomposes in a predetermined amount (for example, 90 mass %) or greater at the firing (annealing) temperature is determined by measuring the mass loss rate (a value obtained by dividing the mass after decomposition by the mass before decomposition) at the firing (annealing) temperature through thermogravimetry (TG).

A thermoplastic resin or a curable resin can be used as the binder resin. Examples of thermoplastic resin include polyolefin resins such as polyethylene, polypropylene, polyisobutylene, and polymethylpentene; polycarbonates; thermoplastic polyester resins such as polyethylene terephthalate and polyethylene naphthalate; polyvinyl polymers such as polystyrene, acrylonitrile-styrene copolymers, poly(vinylacetate), ethylene-vinyl acetate copolymers, vinyl chloride, poly(vinyl pyridine), poly(vinyl alcohol), and poly(vinyl pyrrolidone); polyurethanes; and cellulose derivatives such as ethyl cellulose. Examples of the curable resin include thermosetting resins and photocurable resins. Examples of the thermosetting resins include epoxy resins and phenol resins. Examples of the photocurable resins include photocurable acrylic resins, photocurable urethane resins, and photocurable epoxy resins. One of these may be used alone, or two or more may be used in combination.

The content of the binder resin in the thermoelectric semiconductor composition is from 0.1 to 40 mass %.

### Ionic Liquid

The ionic liquid that may be contained in the thermoelectric semiconductor composition is a molten salt obtained by combining a cation and an anion and is a salt that can be present as a liquid in any temperature region in −50° C. or higher and lower than 400° C. Because the ionic liquid has characteristics such as having a significantly low vapor pressure and being nonvolatile, having excellent thermal stability and electrochemical stability, having a low viscosity, and having a high ionic conductivity, the ionic liquid can effectively suppress reduction of the electrical conductivity between the thermoelectric semiconductor materials as a conductivity aid.

As the ionic liquid, a known or commercially available ionic liquid can be used. Examples thereof include those composed of nitrogen-containing cyclic cation compounds and derivatives thereof, such as pyridinium, pyrimidinium, pyrazolium, pyrrolidinium, piperidinium, and imidazolium; tetraalkylammonium-based amine cations and derivatives thereof; phosphine cations and derivatives thereof, such as phosphonium, trialkylsulfonium, and tetraalkylphosphonium; cation components, such as lithium cation and derivatives thereof; and anion components, such as Cl⁻, Br⁻, I⁻, AlCl₄⁻, Al₂Cl₇⁻, BF₄⁻, PF₆⁻, ClO₄⁻, NO₃⁻, CH₃COO⁻, CF₃COO⁻, CH₃SO₃⁻, CF₃SO₃⁻, (FSO₂)₂N⁻, (CF₃SO₂)₂N⁻, (CF₃SO₂)₃C⁻, AsF₆⁻, SbF₆⁻, NbF₆⁻, TaF₆⁻, F(HF)ₙ⁻, (CN)₂N⁻, C₄F₉SO₃⁻, (C₂F₅SO₂)₂N⁻, C₃F₇COO⁻, and (CF₃SO₂)(CF₃CO)N⁻.

The content of the ionic liquid in the thermoelectric semiconductor composition is preferably from 0.01 to 50 mass %. When the content of the ionic liquid is in the range described above, reduction of the electrical conductivity is effectively suppressed, and a film having a high thermoelectric performance can be obtained.

### Preparation Method of Thermoelectric Semiconductor Composition

A method for preparing the thermoelectric semiconductor composition is not particularly limited, and examples thereof include using known methods such as an ultrasonic homogenizer, a spiral mixer, a planetary mixer, a disperser, or a hybrid mixer to add the thermoelectric semiconductor particles, the ionic liquid, the resin, and if necessary, other additives mentioned above and also add a solvent, and mixing and dispersing them to prepare the thermoelectric semiconductor.

Examples of the solvent include solvents such as toluene, ethyl acetate, methyl ethyl ketone, alcohol, tetrahydrofuran, methyl pyrrolidone, and ethyl cellosolve. One type of solvents may be used alone, or two or more types of these solvents may be mixed and used. As the solid content concentration of the thermoelectric semiconductor composition, the composition is only required to have a viscosity adequate for coating, and the solid content concentration is not particularly limited.

The thermoelectric conversion element composed of the thermoelectric semiconductor composition may be formed in any manner not particularly limited, but may be formed, for example, by coating the thermoelectric semiconductor composition on a base material such as glass, alumina, silicon, or a resin film, or on a base material on a side on which a sacrificial layer described below is formed, to obtain a coating film, drying the coating film, and separating the coating film from the base material as appropriate to obtain the thermoelectric conversion element. By forming in this way, a large number of thermoelectric conversion elements can be obtained simply and at low cost. As the resin film, a film having heat resistance is preferred, and a film composed of a polyamide resin, a polyamide-imide resin, a polyimide resin, or the like is preferable.

A method for applying the thermoelectric semiconductor composition to obtain the thermoelectric conversion element is not particularly limited, and examples thereof include known methods such as screen printing, flexographic printing, gravure printing, spin coating, dip coating, die coating, spray coating, bar coating, and doctor blading. When the coating film is to be formed in a pattern, a method such as screen printing or slot die coating by which the pattern can be easily formed using a screen plate having the desired pattern is preferably used.

Subsequently, the obtained coating film is dried to form a thermoelectric conversion element. As a drying method, a conventionally known method such as hot air drying, hot roll drying, or infrared irradiation can be used. The heating temperature is typically from 80 to 150° C., and while the heating time differs depending on the heating method, the heating time is typically from a few seconds to tens of minutes.

Furthermore, when a solvent is used in the preparation of the thermoelectric semiconductor composition, the heating temperature is not particularly limited as long as the temperature is within a temperature range in which the solvent that is used can be dried.

The thickness of the thermoelectric conversion element is preferably thin, as this helps keep the electric resistance value of the thermoelectric conversion element low, facilitating flowing of the electric current through the thermoelectric conversion element, and thereby increasing the heat absorption amount of the thermoelectric conversion module. Typically, the thickness is 2000 μm or less.

The thickness of the thermoelectric conversion element is preferably 10 to 1600 μm, more preferably 50 to 1400 μm, further preferably 100 to 1200 μm, and particularly preferably 400 to 1000 μm. By ensuring that the thickness of the thermoelectric conversion element is equal to or greater than the lower limit value, it is possible to suppress an increase in the amount of heat generated in the electrodes, solder material layer, and the like, which constitute the π-type thermoelectric conversion module, thereby increasing the heat absorption amount of the thermoelectric conversion module.

The electric resistance value per thermoelectric conversion element M is preferably 30 (mΩ) or less. By keeping the electrical resistance value at 30 (mΩ) or less, the current value per unit area of the thermoelectric conversion element can be increased, making it easier to raise the heat absorption amount to a desired range. The lower limit of the electric resistance value is not particularly limited, but is approximately 0.01 (mΩ) from the perspective of ease of manufacture. From this perspective, the electrical resistance value is preferably from 0.01 to 30 (mΩ), more preferably from 0.1 to 20 (mΩ), still more preferably from 1.0 to 17 (mΩ), and particularly preferably from 6 to 13 (mΩ).

The electric resistance value per each thermoelectric conversion element K is preferably 100 (mΩ) or less. When the electrical resistance value at 100 (mΩ) or less, the current value per unit area of the thermoelectric conversion element can be increased, making it easier to raise the heat absorption amount to a desired range. The lower limit of the electric resistance value is not particularly limited, but is approximately 0.1 (mΩ) from the perspective of ease of manufacture. From this perspective, the electrical resistance is preferably from 0.1 to 100 (mΩ), more preferably from 1 to 60 (mΩ), still more preferably from 10 to 50 (mΩ), and particularly preferably from 30 to 45 (mΩ).

The areas of the upper and lower surfaces of the thermoelectric conversion element M are each independently preferably from 0.04 to 30 (mm²), more preferably from 0.30 to 10 (mm²), still more preferably from 0.5 to 4 (mm²), and particularly preferably from 0.7 to 2 (mm²).

On the other hand, the areas of the upper and lower surfaces of the thermoelectric conversion element K are each independently preferably from 0.01 to 2 (mm²), more preferably from 0.04 to 1 (mm²), still more preferably from 0.06 to 0.9 (mm²), and particularly preferably from 0.1 to 0.6 (mm²).

The ratio of the area of the upper surface to the area of the lower surface of each of the thermoelectric conversion elements M and K is each independently preferably from 0.80 to 1.20, more preferably from 0.90 to 1.10, and still more preferably from 0.99 to 1.01.

When the areas of the upper and lower surfaces of the chip of the thermoelectric conversion element and the ratio of the area of the upper surface of the thermoelectric conversion element to the area of the lower surface of the thermoelectric conversion element are in the range mentioned above, the electric resistance value is suppressed to be low, and the heat absorption amount can be increased easily.

When the upper and lower surfaces of thermoelectric conversion elements M and K are rectangular (overall shape is rectangular parallelepiped shape or cubic shape), the length of one side is preferably from 0.2 to 10 mm, more preferably from 0.5 to 5 mm, and still more preferably from 0.8 to 2 mm.

However, the length of at least one side of the upper and lower surfaces of the thermoelectric conversion element K is shorter than the length of the corresponding portion of the thermoelectric conversion element M. For example, the length of at least one side with respect to the length of the corresponding portion of the thermoelectric conversion element M is preferably from 1 to 90%, more preferably from 5 to 60%, and particularly preferably from 10 to 30%.

When the length of one side of the upper and lower surfaces of the thermoelectric conversion elements M and K and the ratio of the lengths of the respective sides are in the above range, a π-type thermoelectric conversion module having high precision and high heat absorption amount can be manufactured.

The thermoelectric conversion element in the form of a thin film composed of a thermoelectric semiconductor composition is preferably subjected to an annealing treatment (hereinafter referred to as “annealing treatment B”). By subjecting the thermoelectric element layer to the annealing treatment B, the thermoelectric performance can be stabilized, crystal growth of the thermoelectric semiconductor particles in the thin film can be promoted, and the thermoelectric performance can be further improved. The annealing treatment B is not particularly limited, but is typically performed under an inert gas atmosphere such as nitrogen or argon with controlled gas flow, under a reducing gas atmosphere, or under vacuum conditions at a temperature range of 100 to 700° C. for several minutes to several tens of hours depending on the heat resistance temperature of the resin and ionic compounds used. Furthermore, in the annealing treatment B, the thermoelectric semiconductor composition may be pressed to increase the density of the thermoelectric semiconductor composition.

As the sacrificial layer, a resin such as poly(methyl methacrylate) or polystyrene, or a release agent such as a fluorine-based release agent or a silicone-based release agent can be used. By the use of the sacrificial layer, the thermoelectric conversion element formed on the base material such as glass can be easily peeled off the glass after annealing treatment B.

The formation of the sacrificial layer is not particularly limited, and the sacrificial layer can be formed by a known method such as flexographic printing or spin coating.

### Substrate

The substrates for the π-type thermoelectric conversion module of the present invention, namely, the first substrate and the second substrate, are preferably composed of a plastic film, a ceramic substrate, or the like that does not affect the decrease in electrical conductivity and the increase in thermal conductivity of the thermoelectric conversion element. From the perspective of high heat resistance and dimensional stability in that the substrate does not undergo thermal deformation and maintains the performance of the π-type thermoelectric conversion module even when the thermoelectric conversion element is annealed, the following plastic films are preferable: a polyimide film, a polyamide film, a polyetherimide film, a polyaramide film, a polyamide-imide film, and a glass-epoxy sheet.

From the perspectives of flexibility, heat resistance, and dimensional stability, the thickness of the plastic film used in the aforementioned substrate is preferably from 1 to 1000 μm, more preferably from 10 to 500 μm, and even more preferably from 20 to 100 μm. On the other hand, the thickness of the ceramic substrate is preferably from 100 μm to 30 mm, more preferably from 500 μm to 10 mm, and particularly preferably from 1 to 5 mm.

### Electrode

The metal material used for the electrodes in the π-type thermoelectric conversion module of the present invention is not particularly limited, but examples of the metal material of, for example, the first electrode and second electrode include gold, nickel, aluminum, rhodium, platinum, chromium, palladium, stainless steel, molybdenum, or alloys containing any of these metals.

In addition to the metal material, a paste material containing solvents and resin components may also be used for forming. When using the paste material, it is preferable to remove solvents and resin components by firing or other means. The paste material is preferably silver paste or aluminum paste.

The thickness of a layer of the aforementioned electrodes is preferably from 10 nm to 200 μm. When the thicknesses of the respective layers of the electrodes are in the range described above, electrical conductivity is high, resistance is low, and sufficient strength of an electrode is obtained.

Examples of the method for forming the electrodes include known physical or chemical processes mainly using photolithography or a combination thereof to process the material into a predetermined pattern shape, or forming electrode patterns using screen printing, stencil printing, ink jet printing, and the like.

Examples of the method for forming the electrodes without a pattern formed thereon include vacuum deposition including physical vapor deposition (PVD) such as vacuum vapor deposition, sputtering, or ion plating, or chemical vapor deposition (CVD) such as thermal CVD or atomic layer vapor deposition (ALD), a wet process such as dip coating, spin coating, spray coating, gravure coating, die coating, doctor blading, and other coating or electroplating methods, a silver halide process, electroplating, electroless plating, and layering of metal foils. The method is employed with appropriate selection based on the type of metal material.

### Solder Material Layer

The solder material layer is used to bond the thermoelectric conversion element and the conductive layer.

Examples of the solder material constituting the solder material layer include known materials such as Sn, Sn/Pb alloys, Sn/Ag alloys, Sn/Cu alloys, Sn/Sb alloys, Sn/In alloys, Sn/Zn alloys, Sn/In/Bi alloys, Sn/In/Bi/Zn alloys, Sn/Bi/Pb/Cd alloys, Sn/Bi/Pb alloys, Sn/Bi/Cd alloys, Bi/Pb alloys, Sn/Bi/Zn alloys, Sn/Bi alloys, Sn/Bi/Pb alloys, Sn/Pb/Cd alloys, and Sn/Cd alloys.

Examples of commercially available solder material products that can be used include the following. For example, a 42Sn/58Bi alloy (available from Tamura Corporation, product name: SAM10-401-27), a 41Sn/58Bi/Ag alloy (available from NIHON HANDA Co., Ltd., product name: PF141-LT7HO), a 96.5Sn3Ag0.5Cu alloy (available from NIHON HANDA Co., Ltd., product name: PF305-207BTO), and the like can be used.

The thickness of the solder material layer (after heating and cooling) is preferably from 10 to 200 μm. When the thickness of the solder material layer is in this range, adhesion with the thermoelectric conversion element and the conductive layer is easily provided.

Examples of the method for applying the solder material to a substrate include known methods such as stencil printing, screen printing, and dispensing. The heating temperature varies depending on the solder material, resin film, and the like used, but is typically performed at 150 to 280° C. for 3 to 20 minutes.

### Heat Dissipation Layer

In the π-type thermoelectric conversion module of the present invention, from the perspective of thermoelectric performance, a heat dissipation layer is further provided preferably on at least one of the surfaces of the substrate described above.

The material used for the heat dissipation layer is not particularly limited, and any known material can be used. Preferably, the material is selected from gold, silver, copper, nickel, tin, iron, chromium, platinum, palladium, rhodium, iridium, ruthenium, osmium, indium, zinc, molybdenum, manganese, titanium, aluminum, stainless steel, and brass.

The method for laminating the heat dissipation layer is not particularly limited, and examples thereof include a dry process such as physical vapor deposition (PVD) such as vacuum vapor deposition, sputtering, or ion plating, and chemical vapor deposition (CVD) such as thermal CVD or atomic layer vapor deposition (ALD), a wet process such as dip coating, spin coating, spray coating, gravure coating, die coating, doctor blading, and other coating or electroplating methods, silver halide process, electroplating, electroless plating, and the like.

The patterning of the heat dissipation layer can be performed by known physical or chemical processes mainly using photolithography or a combination thereof.

The thermal conductivity of the heat dissipation layer is preferably from 5 to 500 W/(m·K) independently for each layer.

The thickness of the heat dissipation layer is determined appropriately from the perspective of thermoelectric performance, but is preferably from 1 to 550 μm.

The calculated heat absorption amount per unit area of one unit (a pair of thermoelectric conversion member A and heat back-flow suppression member B) constituting the thermoelectric conversion module is preferably from 1 to 30 W/cm², more preferably from 2.5 to 10 W/cm², and particularly preferably from 3.5 to 5.0 W/cm². When the calculated heat absorption amount is in the above range, the thin film thermoelectric conversion module with high heat absorption amount can be obtained easily.

The total thickness of the π-type thermoelectric conversion module is preferably from 300 μm to 20 mm.

When the total thickness of the π-type thermoelectric conversion module is in this range, the module resistance value of the thermoelectric conversion module is easily suppressed, and the thin π-type thermoelectric conversion module with high cooling performance can be obtained.

The π-type thermoelectric conversion module of the present invention has excellent cooling performance with suppressed back-flow of heat.

### EXAMPLES

The present invention will now be described in greater detail by way of examples, but the present invention is in any way not limited by these examples.

The heat absorption amounts of the π-type thermoelectric conversion module of the present invention, the π-type thermoelectric conversion module of the related art, and the uni-leg-type thermoelectric conversion module were evaluated using the following method.

### (a) Evaluation of Heat Absorption Amount

The cooling performance (heat absorption amount per unit area) of the thermoelectric conversion modules of Examples 1 and 2 and Comparative Examples 1 and 2 was evaluated using the aforementioned thermal simulation for one unit (a pair of thermoelectric conversion member A and heat back-flow suppression member B).

### Example 1

A thermal simulation was performed on the π-type thermoelectric conversion module of the embodiment (Configuration A) illustrated in FIG. 1, and the heat absorption amount per unit area was evaluated.

First, the temperature of the cooling surface (heat absorption surface) was set to 50° C., and the temperature of the heat dissipation surface was set to 70° C.

The physical property values of the thermoelectric conversion member A, the physical property values of the heat back-flow suppression member B, the current value of the thermoelectric conversion module, and the electric resistance value of the thermoelectric conversion module, and the like were set as follows.

### Thermoelectric Conversion Member A

### Thermoelectric Conversion Element M [P-Type (BiSbTe-Based)]

Size: Upper and lower surfaces having rectangular parallelepiped shape measuring 1 mm long×1 mm wide and a thickness of 1 mm
Se: Seebeck coefficient [183×10⁻⁶ (V/K)]
I: Current value of thermoelectric conversion module [1(A)]
T_{c}: Temperature of the heat absorption surface of the thermoelectric conversion module [273.15+50 (K)]
Tₕ: Temperature of heat dissipation surface of the thermoelectric conversion module [273.15+70 (K)]
ΔT: Temperature difference (Tₕ−T_{c}) [20 (K)]
R: Electric resistance value of one thermoelectric conversion element M [10.5 (mΩ)]
λ: Thermal conductivity of thermoelectric conversion element M [1.02 [W/(m·K)]]
L: Height (thickness) of thermoelectric conversion element M [1×10⁻³ (m)]
S: Area of surface side of thermoelectric conversion element M bonded to first and second electrodes [1×10⁻⁶ (m²)]

### Heat Back-Flow Suppression Member B

### Thermoelectric Conversion Element K [N-Type (BiTe-Based)]

Size: Upper and lower surfaces having rectangular parallelepiped shape measuring 1 mm long×0.2 mm wide and a thickness of 1 mm
Se: Seebeck coefficient [−132×10⁻⁶ (V/K)]
I: Current value of thermoelectric conversion module [1(A)]
T_{c}: Temperature of the heat absorption surface of the thermoelectric conversion module [273.15+50 (K)]
Tₕ: Temperature of heat dissipation surface of the thermoelectric conversion module [273.15+70 (K)]
ΔT: Temperature difference (Tₕ−T_{c}) [20 (K)]
R: Electric resistance value of one thermoelectric conversion element K [44.7 (mΩ)]
λ: Thermal conductivity of thermoelectric conversion element K [1.02 [W/(m·K)]]
L: Height (thickness) of thermoelectric conversion element K [1×10⁻³ (m)]
S: Area of surface side of thermoelectric conversion element K bonded to first and second electrodes [0.2×10⁻⁶ (m²)]
Conductive member: None
Distance between thermoelectric conversion element M and thermoelectric conversion element K: 0.1 mm

From the above, the unit area including the thermoelectric conversion element M, the thermoelectric conversion element K, and the interval therebetween was 1.3 mm².

### Example 2

In Example 1, the π-type thermoelectric conversion module of the embodiment (Configuration B) was changed to the one illustrated in FIG. 2. In the heat back-flow suppression member B, the thickness of thermoelectric conversion element K [N-type (BiTe-based)] was set to 0.2 mm, and copper having the following size and thermal conductivity was newly used as a conductive member. The same procedure as in Example 1 was followed, except for the above, and thermal simulation was performed to evaluate the heat absorption amount per unit area.
Size: Upper and lower surfaces having rectangular parallelepiped shape measuring 1 mm long×0.2 mm wide and a thickness of 0.8 mm
λ: Thermal conductivity [398 [W/(m·K)]]

(Here, the electric resistance value of the conductive member was calculated as 0 mΩ.)
R: Electric resistance value of one thermoelectric conversion element K [8.9 (mΩ)]

### Comparative Example 1

In Example 1, the π-type thermoelectric conversion module of the embodiment (Configuration C) was changed to the one (uni-leg type) illustrated in FIG. 3. In the heat back-flow suppression member B, copper having the following size and thermal conductivity was used as a conductive member instead of the thermoelectric conversion element K [N-type(BiTe-based)]. The same procedure as in Example 1 was followed, except for the above, and thermal simulation was performed to evaluate the heat absorption amount per unit area.
Size: Rectangular parallelepiped shape of upper and lower surfaces measuring 1 mm long×0.2 mm wide and a thickness of 1.0 mm.
λ: Thermal conductivity [398 [W/(m·K)]]

### Comparative Example 2

In Example 1, the π-type thermoelectric conversion module of the embodiment (Configuration D) was changed to the one illustrated in FIG. 4. In the heat back-flow suppression member B, the size of the thermoelectric conversion element K [N-type (BiTe-based)] was changed as follows. The same procedure as in Example 1 was followed, except for the above, and thermal simulation was performed to evaluate the heat absorption amount per unit area.
Size: Upper and lower surfaces having rectangular parallelepiped shape measuring 1 mm long×1.0 mm wide and a thickness of 1.0 mm

Table 1 shows the simulation results of the heat absorption amounts of the thermoelectric conversion module obtained in Examples 1 and 2 (π-type), Comparative Example 1 (uni-leg type), and Comparative Example 2 (π-type).

TABLE 1

| | π-Type Thermoelectric Conversion Module | | | | | | | | | |
|---|---|---|---|---|---|---|---|---|---|---|
| | Thermoelectric | | | | | | | | | |
| | conversion member A | | Heat back-flow suppression member B | | | | | | | |
| | Thermoelectric | | Thermoelectric | | | | | | | |
| | conversion element M | | conversion element K | | Conductive member | | | | | |
| | | Upper and lower | | Upper and lower | | Upper and lower | | | | |
| | | surfaces: length × | | surfaces: length × | | surfaces: length × | | | | Heat |
| | | width × height | | width × height | | with × height | | | | absorption |
| | Material | (thickness) | Material | (thickness) | Material | (thickness) | *S_{A} | *S_{B} | Ratio R | amount |
| | type | [mm] | type | [mm] | type | [mm] | (mm²) | (mm²) | S_{A}/(S_{A} + S_{B}) | (W/cm²) |
| Example 1 | P-type | 1 × 1 × 1 | N-type | 1 × 0.2 × 1 | — | — | 2 | 0.4 | 0.83 | 3.8 |
| | (BiSbTe- | | BiTe- | | | | | | | |
| | based) | | based) | | | | | | | |
| Example 2 | P-type | 1 × 1 × 1 | N-type | 1 × 0.2 × 0.2 | Cu | 1 × 0.2 × 0.8 | 2 | 0.4 | 0.83 | 3.9 |
| | (BiSbTe- | | (BiTe- | | | | | | | |
| | based) | | based) | | | | | | | |
| Comparative | P-type | 1 × 1 × 1 | N-type | — | Cu | 1 × 0.2 × 1 | 2 | 0.4 | 0.83 | Heat |
| Example 1 | (BiSbTe- | | (BiTe- | | | | | | | back- |
| | based) | | based) | | | | | | | flow |
| Comparative | P-type | 1 × 1 × 1 | N-type | 1 × 1 × 1 | — | — | 2 | 2 | 0.5 | 2.4 |
| Example 2 | (BiSbTe- | | (BiTe- | | | | | | | |
| | based) | | based) | | | | | | | |

*S_{A}: Sum of areas of surface sides of the thermoelectric conversion member A bonded to the first and second electrodes
*S_{B}: Sum of areas of surface sides of the heat back-flow suppression member B bonded to the first and second electrodes

As shown in Table 1, the π-type thermoelectric conversion modules of Examples 1 and 2 which satisfy the provisions of the present invention, exhibit higher heat absorption amounts than the uni-leg-type thermoelectric conversion module of the related art in Comparative Example 1 and the π-type thermoelectric conversion module of the related art in Comparative Example 2, both of which do not satisfy the provisions of the present invention.

### INDUSTRIAL APPLICABILITY

According to the π-type thermoelectric conversion module of the present invention having excellent cooling performance with suppressed back-flow of heat, it can be used for cooling applications in the field of electronic devices as central processing units (CPUs) used in smartphones, various computers, and the like, complementary metal oxide semiconductor (CMOS) and charge-coupled device (CCD) used in image sensors, micro-electromechanical systems (MEMS), and other light-receiving elements or the like for temperature control thereof.

### REFERENCE SIGNS LIST

1 π-type thermoelectric conversion module
11 π-type thermoelectric conversion module
21 Thermoelectric conversion module (uni-leg type)
31 π-type thermoelectric conversion module (conventional type)
2a First substrate
2b Second substrate
3a First electrode
3b Second electrode
4a Thermoelectric conversion member A
4a₁ Thermoelectric conversion element M
4b Heat back-flow suppression member B
4b₁ Thermoelectric conversion element K
4b₂ Conductive member

1. A π-type thermoelectric conversion module, comprising:
a pair of a first substrate including a first electrode and a second substrate including a second electrode, the first substrate and the second substrate opposing each other;
a thermoelectric conversion member A including a thermoelectric conversion element M; and
a heat back-flow suppression member B including a thermoelectric conversion element K,
the thermoelectric conversion member A and the heat back-flow suppression member B being arranged alternately and apart from each other between the first and second substrates, and electrically connected in series via the first electrode on the first substrate and the second electrode on the second substrate, wherein
carriers of the thermoelectric conversion element M and the thermoelectric conversion element K are different from each other, one of the carriers being a hole and the other of the carriers being an electron, and
a sum S_{A} (m²) of areas of surface sides of the thermoelectric conversion member A bonded to the first electrode and the second electrode is larger than a sum S_{B} (m²) of areas of surface sides of the heat back-flow suppression member B bonded to the first electrode and the second electrode.

2. The π-type thermoelectric conversion module according to claim 1, wherein
a ratio R [=S_{A}/(S_{A}+S_{B}] of the sum S_{A} of the areas of the surface sides of the thermoelectric conversion member A bonded to the first electrode and the second electrode to a sum of the sum S_{A} of the areas of the surface sides of the thermoelectric conversion member A bonded to the first electrode and the second electrode and the sum S_{B} of the areas of the surface sides of the heat back-flow suppression member B bonded to the first electrode and the second electrode is 0.55 or more and less than 0.95.

3. The π-type thermoelectric conversion module according to claim 1, wherein
the heat back-flow suppression member B includes the thermoelectric conversion element K and a conductive member, and
the thermoelectric conversion element K and the conductive member are laminated in a direction in which the first substrate and the second substrate face each other.

4. The π-type thermoelectric conversion module according to claim 3, wherein
a height of the thermoelectric conversion element M in a thickness direction of the thermoelectric conversion member A is greater than a height of the thermoelectric conversion element K in a thickness direction of the heat back-flow suppression member B including the conductive member.
